(19) United States
(12) Patent Application Publication
(10) Pub. No.: US 2014/0110249 A1
(43) Pub. Date: Apr. 24, 2014

(54) SPUTTERING TARGET, METHOD FOR MANUFACTURING SAME, AND METHOD FOR MANUFACTURING THIN FILM TRANSISTOR

(71) Applicants: Yohsuke Kanzaki, Osaka (JP); Takatsugu Kusumi, Osaka (JP); Naohiro Tamari, Osaka (JP); Masao Moriguchi, Osaka (JP)

(72) Inventors: Yohsuke Kanzaki, Osaka (JP); Takatsugu Kusumi, Osaka (JP); Naohiro Tamari, Osaka (JP); Masao Moriguchi, Osaka (JP)

(73) Assignee: Sharp Kabushiki Kaisha, Osaka (JP)

(21) Appl. No.: 14/002,674

(22) PCT Filed: Feb. 24, 2012
(86) PCT No.: PCT/JP2012/054533

§ 371 Date: Sep. 19, 2013

(30) Foreign Application Priority Data
Mar. 4, 2011 (JP) 2011-047128

(51) Int. Cl. C23C 14/34; H01L 21/203

(52) U.S. Cl. CPC C23C 14/3407; H01L 21/203
USPC 204/192.25; 204/298.12; 204/298.13; 29/428

(57) ABSTRACT

The purpose of the present invention is to provide a sputtering target with which a film having excellent characteristics can be obtained. A sputtering target (100) is constituted of a plurality of target members (10), a backing plate (20), a bonding agent (30), and protective members (50). The plurality of target members (10) and the backing plate (20) are bonded to each other with the bonding agent (30) therebetween. On a backing plate (20) surface that corresponds in position to gaps (15) between adjacent target members (10), grooves (40) are formed. Each of the grooves (40) is provided with the protective members (50), which are composed of the same material as that of the target members (10). The width (W2) of the protective members (50) is greater than the width (W1) of the gaps (15), and is less than the width (W3) of the grooves (40). The thickness (T4) of the protective members (50) is larger than the depth (D1) of the grooves (40).

### TECHNICAL FIELD

The present invention relates to a sputtering target, a method for manufacturing the same, and a method for manufacturing a thin film transistor, and in particular, relates to a segmented sputtering target including a plurality of target members, a method for manufacturing the same, and a method for manufacturing a thin film transistor using this sputtering target.

### BACKGROUND ART

Attention has been paid to thin film transistors (TFTs) that use oxide semiconductors as the channel layers thereof up until now. Oxide semiconductor films have high mobility and have a high transmission of visible light, and are thus used in various applications such as liquid crystal display devices. Among oxide semiconductor films, those made of InGaZnO_{X} (hereinafter referred to as “IGZO”), which is an oxide semiconductor having indium (In), gallium (Ga), zinc (Zn), and oxygen (O) as main components, are known, for example.

One known method to form such an oxide semiconductor film is sputtering. Sputtering targets used in sputtering generally have a configuration in which a target member made of a material to be formed into the thin film, and a supporting member made of a material with excellent electrical and heat conductivity such as copper (Cu) are bonded together through a bonding agent made of In or the like.

In magnetron sputtering, which is a type of sputtering, sputtering is performed by disposing a magnet on the rear of the sputtering target. Magnetron sputtering allows fast film-forming. Thus, magnetron sputtering is widely used in forming an oxide semiconductor film.

In recent years, display panels such as liquid crystal display devices have become larger in size. As a result, it has become necessary to also make the target member larger in size. However, forming a large target member is generally difficult. Thus, a segmented sputtering target in which a plurality of target members are provided in a plate shape on a supporting member is proposed. With such a configuration, it is possible to have a larger sputtering target by increasing the number of target members.

In order to prevent cracks and the like in the target member, in a segmented sputtering target, target members adjacent to each other generally have a small gap at the seam therebetween. As a result of the gap, the supporting member is exposed at the seams. Also, the bonding agent overflows at the seam. As a result, the supporting member and bonding agent, which are materials that should not normally be sputtered, are sputtered. As a result, the material sputtered from the supporting member and bonding agent is included as impurities in the semiconductor film. This results in worse semiconductor film characteristics.

In relation to the present invention, Patent Document 1 discloses a sputtering target in which a groove is formed in the supporting member directly under the seam, with the groove being filled with a small amount of the same material as the target member. Patent Document 2 discloses a sputtering target provided with a protective member made of a material that is not susceptible to being sputtered or the same material as the target member at the seams. With the sputtering target disclosed in Patent Document 1 or 2, it is possible to prevent material from the supporting member from being sputtered and included in the thin film.

### RELATED ART DOCUMENTS

### Patent Documents

Patent Document 1: Japanese Patent Application Laid-Open Publication No. 563-100177
Patent Document 2: Japanese Patent Application Laid-Open Publication No. H10-121232

### SUMMARY OF THE INVENTION

### Problems to be Solved by the Invention

However, in the sputtering target disclosed in Patent Document 1 or 2, there is a small space between the target member and the small amount of material (protective member). As a result, the bonding agent overflows at the seams, which results in the bonding agent being sputtered. As a result, the sputtered bonding agent is included as an impurity in the semiconductor film. This results in worse semiconductor film characteristics.

An object of the present invention is to provide a sputtering target with which it is possible to obtain a film with excellent characteristics.

Another object of the present invention is to provide a manufacturing method for a sputtering target with which it is possible to obtain a film with excellent characteristics.

Another object of the present invention is to provide a manufacturing method for a thin film transistor using a sputtering target with which it is possible to obtain a semiconductor film with excellent characteristics.

### Means for Solving the Problems

A first aspect of the present invention is a sputtering target, includes:

a plurality of target members made of the same material as each other;

a supporting member that supports the plurality of target members;

a bonding agent that bonds the plurality of target members to the supporting member; and

a protective member made of the same material as the respective target members,

wherein a portion of a surface of the supporting member corresponding in position to a seam between adjacent target members has a groove therein,

wherein a width of the groove is greater than a width of the seam,

wherein a width of the protective member is greater than the width of the seam and less than the width of the groove,

wherein the protective member is provided in the groove,

wherein a surface of the protective member protrudes above the surface of the supporting member, and

wherein portions of the surface of the protective member are in contact with portions of the respective adjacent target members.

In a second aspect, the present invention is the first aspect of the present invention,

wherein the respective target members and the protective member are made of a semiconductor.

In a third aspect, the present invention is the second aspect of the present invention,

wherein the semiconductor is an oxide semiconductor.

In a fourth aspect, the present invention is the third aspect of the present invention,

wherein the oxide semiconductor includes indium, gallium, zinc, and oxygen as main components.

In a fifth aspect, the present invention is the third aspect of the present invention,

wherein the oxide semiconductor includes at least one of indium, gallium, zinc, copper, silicon, tin, aluminum, calcium, germanium, and lead.

In a sixth aspect, the present invention is the second aspect of the present invention,

wherein a thickness of the protective member is greater than a depth of the groove.

In a seventh aspect, the present invention is the second aspect of the present invention,

wherein the supporting member has a plate shape, and

wherein the respective target members have plate shapes.

In an eighth aspect, the present invention is the second aspect of the present invention,

wherein the supporting member has a hollow cylindrical shape or a non-hollow cylindrical shape, and

wherein the respective target members have hollow cylindrical shapes.

In a ninth aspect, the present invention is the second aspect of the present invention,

wherein the protective member is provided in a position corresponding to a portion where erosion of the plurality of target members progresses quickly.

A tenth aspect of the present invention is a method of manufacturing a thin film transistor, including forming a channel layer by sputtering the sputtering target according to any one of the second aspect to the ninth aspect of the present invention.

An eleventh aspect of the present invention is a method of manufacturing a sputtering target that includes a plurality of target members made of the same material as each other, a supporting member that supports the plurality of target members, and a bonding agent that bonds together the plurality of target members and the supporting member, the method including:

forming a groove in a portion of a surface of the supporting member corresponding in position to a seam between adjacent target members; and

embedding a protective member made of the same material as the respective target members into the groove,

wherein a width of the groove is greater than a width of the seam,

wherein a width of the protective member is greater than the width of the seam and less than the width of the groove,

wherein the protective member is provided in the groove,

wherein a surface of the protective member protrudes above the surface of the supporting member, and

wherein portions of the surface of the protective member are in contact with portions of the respective adjacent target members.

### Effects of the Invention

According to the first aspect of the present invention, a protective member made of the same material as the target members is provided on the surface of the supporting member corresponding in position to the seam. The protective member and the target members are in direct contact with each other, and spaces are formed between the respective side faces of the protective member and the supporting member, and thus, overflow of the bonding agent at the seam is sufficiently mitigated. Thus, the supporting member and the bonding agent are not sputtered at the seam. As a result, it is possible to prevent material from the supporting member and the bonding agent from being mixed into the film to be formed as impurities, thus allowing a film with excellent characteristics to be obtained.

According to the second aspect of the present invention, it is possible to obtain a semiconductor film with excellent characteristics.

According to the third aspect of the present invention, it is possible to obtain an oxide semiconductor film with excellent characteristics.

According to the fourth aspect of the present invention, it is possible to obtain an IGZO semiconductor film with excellent characteristics.

According to the fifth aspect of the present invention, it is possible to obtain a so-called IGZO-type oxide semiconductor film with excellent characteristics.

According to the sixth aspect of the present invention, the thickness of the protective member is greater than the depth of the groove, and thus, effects similar to those of the second aspect of the present invention can be attained.

According to the seventh aspect of the present invention, in a sputtering target in which the target members are plate-shaped, effects similar to those of the second aspect of the present invention can be attained.

According to the eighth aspect of the present invention, in a sputtering target in which the target members are hollow cylinders, effects similar to those of the second aspect of the present invention can be attained.

According to the ninth aspect of the present invention, it is possible to fill portions where the protective member is unneeded with the bonding agent. With this configuration, it is possible to improve the bonding strength between the target members and the supporting member.

According to the tenth aspect of the present invention, it is possible to obtain a thin film transistor having formed therein a channel layer with excellent characteristics.

According to the eleventh aspect of the present invention, it is possible to manufacture a sputtering target with which it is possible to obtain a film with excellent characteristics.

### BRIEF DESCRIPTION OF THE DRAWINGS

FIG. 1 is a plan view of a sputtering target according to Embodiment 1 of the present invention.

FIG. 2 is a cross-sectional view along the line A-A′ of the sputtering target shown in FIG. 1.

FIG. 3 is a magnified view of a portion of the cross-sectional view of FIG. 2.

FIGS. 4(A) to 4(D) show a method of manufacturing the sputtering target according to Embodiment 1.

FIGS. 5(A) to 5(D) show magnified views of respective portions of FIGS. 4(A) to 4(D).

FIG. 6 is a cross-sectional view of a configuration of a TFT in which the channel layer thereof is formed using the sputtering target of Embodiment 1.

FIGS. 7(A) to 7(D) are cross-sectional views for describing steps for manufacturing the TFT of Embodiment 1.

FIGS. 8(A) and 8(B) are cross-sectional views for describing steps for manufacturing the TFT of Embodiment 1.

FIG. 9 shows a portion of an active matrix substrate where the TFT shown in FIG. 6 is provided as a pixel TFT.

FIG. 10 shows characteristics of the TFT in which the channel layer thereof is formed using the sputtering target of Embodiment 1.

FIG. 11 is a plan view of a sputtering target according to Modification Example 1 of Embodiment 1.

FIG. 12 is a plan view of a sputtering target according to Modification Example 2 of Embodiment 1.

FIG. 13 is a cross-sectional view of a sputtering target according to Modification Example 3 of Embodiment 1.

FIG. 14 is a cross-sectional view of another example of Modification Example 3 of Embodiment 1.

FIG. 15 is a perspective view of a sputtering target according to Embodiment 2 of the present invention.

FIG. 16 is a cross-sectional view along the line B-B′ of the sputtering target shown in FIG. 15.

FIG. 17 is a magnified view of a portion of the cross-sectional view of FIG. 16.

FIGS. 18(A) to 18(C) show a method of manufacturing the sputtering target according to Embodiment 2.

FIGS. 19(A) and 19(B) show a method of manufacturing the sputtering target according to Embodiment 2.

FIG. 20 is a plan view of a conventional sputtering target.

FIG. 21 is a cross-sectional view along the line C-C′ of the sputtering target shown in FIG. 20.

FIG. 22 is a magnified view of a portion of the cross-sectional view of FIG. 21.

FIG. 23 is a cross-sectional view showing a configuration of a TFT in which the channel layer thereof is formed using a conventional sputtering target.

FIG. 24 is a schematic view for describing DC magnetron sputtering.

FIG. 25 shows characteristics of TFTs in which the channel layers thereof are formed using a conventional sputtering target.

### DETAILED DESCRIPTION OF EMBODIMENTS

### 0. Basic Study

Before describing embodiments of the present invention, a basic study conducted by inventors of the present invention in order to solve the above-mentioned problems will be described.

### 0.1 Configuration of Conventional Sputtering Target

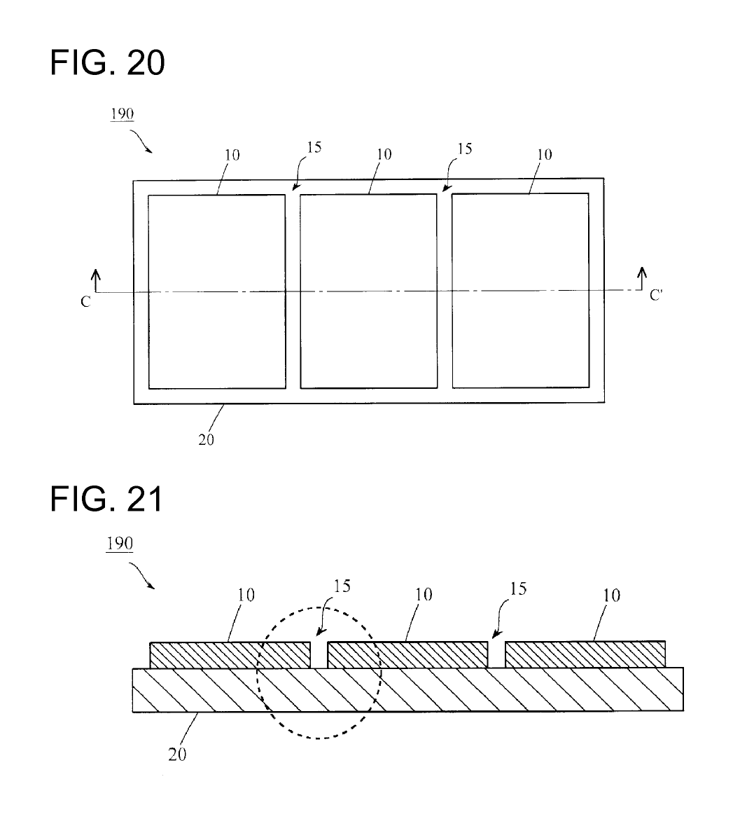

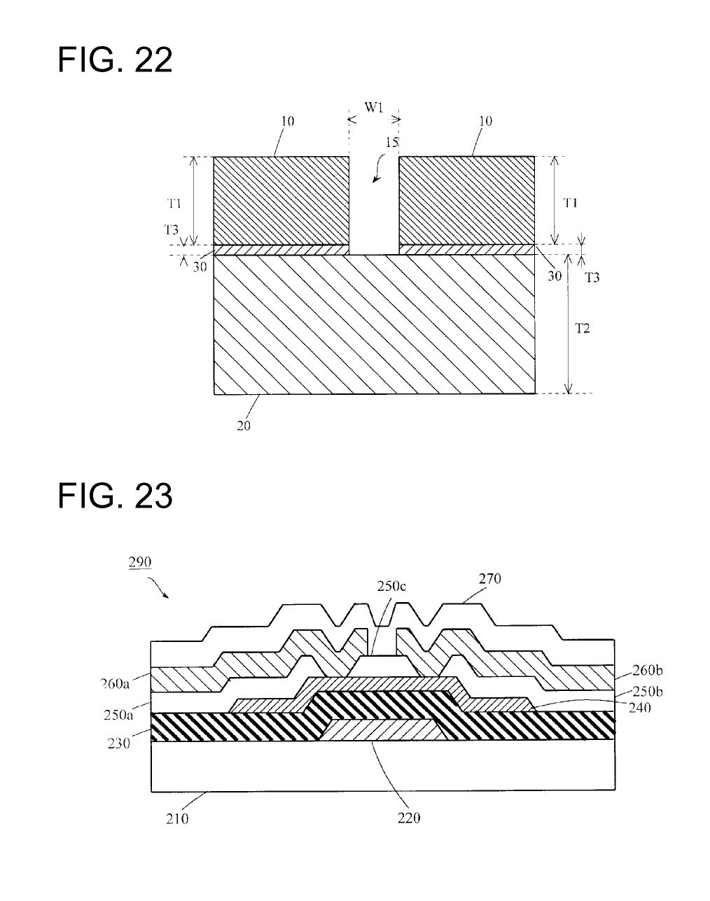

A configuration of a conventional sputtering target will be described with reference to FIGS. 20 to 22. FIG. 20 is a plan view of a configuration of a conventional sputtering target 190. FIG. 21 is a cross-sectional view along the line C-C′ of the sputtering target 190 shown in FIG. 20. FIG. 22 is a magnified view of a portion (portion surrounded by the dotted line) of the cross-sectional view of FIG. 21.

The sputtering target 190 is a segmented sputtering target constituted of a plurality of plate-shaped target members 10, a backing plate 20, and a bonding agent 30. FIGS. 20 and 21 show an example of three target members 10 being aligned in the horizontal direction. The respective target members 10 are made of a material with which a thin film is to be formed. The respective target members 10 in the present basic study are made of IGZO, which is an oxide semiconductor having In, Ga, Zn, and O as main components. The backing plate 20 is made of Cu or the like. The bonding agent 30 is made of In or the like. The plurality of target members 10 and the backing plate 20 are bonded together through the bonding agent 30. In order to prevent cracking and the like in the target members 10, small gaps are provided in seams 15 between adjacent target members 10. As shown in FIG. 22, in general, the surface of the backing plate 20 is exposed at the seams 15.

### 0.2 Configuration of TFT

FIG. 23 is a cross-sectional view showing a configuration of a TFT 290 in which the channel layer thereof is formed using the conventional sputtering target 190. As shown in FIG. 23, the TFT 290 is a bottom gate TFT having an etching stopper structure.

A gate electrode 220 is formed on an insulating substrate 210 made of glass or the like. The gate electrode 220 is a multilayer film having a titanium (Ti) film 30 nm in thickness, an aluminum (Al) film 200 nm in thickness, and a Ti film 100 nm in thickness, layered in that order.

On the gate electrode 220, a gate insulating film 230 is formed so as to cover the gate electrode 220. The gate insulating film 230 is a multilayer film having a silicon nitride (SiN_{X}) film 325 nm in thickness, and a silicon oxide (SiO₂) film 50 nm in thickness, layered in that order.

A channel layer 240 made of IGZO is formed on the gate insulating film 230. A method to form the channel layer 240 will be described later.

In the upper left, upper right, and upper center of the channel layer 240 in FIG. 23, etching stopper layers 250a, 250b, and 250c made of SiO₂ 150 nm in thickness are respectively formed.

A source electrode 260a is formed so as to cover the etching stopper layer 250a, a portion of the surface of the channel layer 240 exposed between the etching stopper layers 250a and 250c, and the left edge of the etching stopper layer 250c. A drain electrode 260b is formed so as to cover the etching stopper layer 250b, a portion of the surface of the channel layer 240 exposed between the etching stopper layers 250b and 250c, and the right edge of the etching stopper layer 250c. A contact hole is formed between the etching stopper layers 250a and 250c, and the source electrode 260a is connected to the channel layer 240 through the contact hole. Similarly, a contact hole is formed between the etching stopper layers 250b and 250c, and the drain electrode 260b is connected to the channel layer 240 through the contact hole. The source electrode 260a and the drain electrode 260b are multilayer films having a Ti film 30 nm in thickness and an Al film 200 nm in thickness layered in this order. For the source electrode 260a and the drain electrode 260b, a single metal film such as Ti, Al, Cu, molybdenum (Mo), tungsten (W), or chromium (Cr), an alloy film including titanium nitride (TiN) or molybdenum nitride (MoN), or a multilayer film including these may be used instead of the above-mentioned multilayer film.

A protective film 270 made of SiO₂ 200 nm in thickness is formed so as to cover the entire insulating substrate 210 over which the source electrode 260a and the drain electrode 260b are formed.

### 0.3 Forming Channel Layer

The channel layer 240 is formed by magnetron sputtering. Magnetron sputtering includes DC (direct current) magnetron sputtering and RF (radio frequency) magnetron sputtering. Although either DC magnetron sputtering or RF magnetron sputtering may be used to form a semiconductor film made of IGZO, in the description below, DC magnetron sputtering is used.

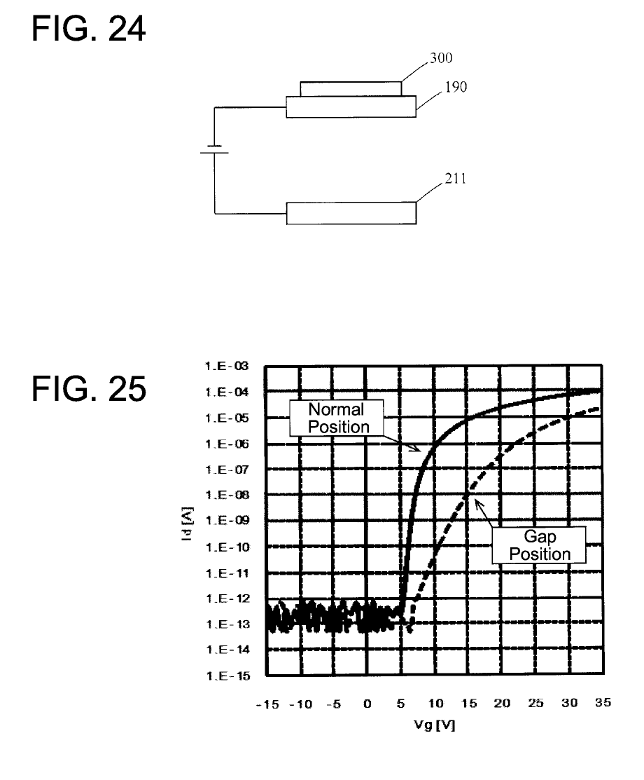

As shown in FIG. 24, in DC magnetron sputtering, a magnet 300 is disposed on the rear surface (surface on the backing plate 20 side) of the sputtering target 190, and a DC voltage is applied between the sputtering target 190 with the magnet 300 disposed on the rear surface thereof, and a substrate 211. The substrate 211 is the insulating substrate 210 up to when the gate electrode 220 and the gate insulating film 230 have been layered on the surface thereof. Argon (Ar) gas or the like is used as the sputtering gas. Although a plurality of magnets 300 are normally used, in FIG. 24, only one is shown for ease of depiction.

As a DC voltage is applied, Ar ions are accelerated, and collide with the surface of the target members 10 of the sputtering target 190. As a result, atoms are flicked off (sputtered) from the surface of the target members 10, and reach the substrate 211. As the sputtered material from the target members 10 is deposited onto the substrate 211, the semiconductor film is formed. In magnetron sputtering, the magnet 300 is disposed on the rear surface of the sputtering target 190, and thus, the helical path of the electrons is bound. Thus, a high density plasma is generated in the vicinity of the target members 10. As a result, high speed film-forming can be performed.

### 0.4 Study

The inventors of the present invention conducted an experiment to measure characteristics of the TFT 290 in which the channel layer 240 thereof is formed using the conventional sputtering target 190. In the sputtering target 190 used in this experiment, the respective target members 10 had a thickness T1 of 6.0 mm, the backing plate 20 had a thickness T2 of 10.0 mm, the bonding agent 30 had a thickness T3 of 0.3 mm, and the seam 15 had a width W1 of 0.3 mm. The length of the channel of the TFT 290 was 8 μm, and the width of the channel was 20 μm.

FIG. 25 shows the Id-Vg characteristics of the TFTs 290 in which the channel layers 240 thereof were formed using the conventional sputtering target 190. Here, Id represents the drain current, and Vg represents the gate voltage. The solid line represents the characteristics of a TFT 290 formed in a position other than a position corresponding to the seam 15 between the target members 10 (hereinafter referred to as the “normal position”), and the dotted line represents the characteristics of a TFT 290 formed in a position corresponding to the seam 15 between the target members 10 (hereinafter referred to as the “seam position”).

As shown in FIG. 25, TFTs 290 formed at the seam positions have a worse startup of the Id-Vg characteristics compared to the TFTs 290 formed at the normal positions. Reasons are as follows. In the sputtering target 190, the backing plate 20 is exposed at the seams 15 between the target members 10. Also, the bonding agent 30 overflows at the seams 15. As a result, material from the backing plate 20 and the bonding agent 30, which normally should not be sputtered, is sputtered. As a result, material sputtered from the backing plate 20 and bonding agent 30 is mixed into the semiconductor film as impurities, thus worsening the characteristics of the semiconductor film. As a result, TFTs 290 formed at the seam positions have a lower mobility, a higher threshold voltage, and the like.

If, in order to prevent such a worsening of characteristics in the TFTs 290, the sputtering target disclosed in Patent Document 1 or 2 is used, the small spaces between the target members 10 and the protective members become a problem. In other words, as a result of the bonding agent 30 overflowing at the seams as described above, this bonding agent 30 is sputtered. As a result, the sputtered bonding agent 30 is included as an impurity in the semiconductor film. This results in worse semiconductor film characteristics.

Also, the width of the seams 15 is very narrow, and thus, it is difficult to provide the bonding agent 30 at an even thickness while preventing the bonding agent 30 from overflowing at the seams. Furthermore, when heating the target members 10, there is a possibility of a melted bonding agent 30 oozing into the seams 15 due to capillary action.

Based on the basic study above, embodiments of the present invention made by inventors of the present invention will be described below with reference to the appended drawings.

### 1. Embodiment 1

### 1.1 Configuration of Sputtering Target

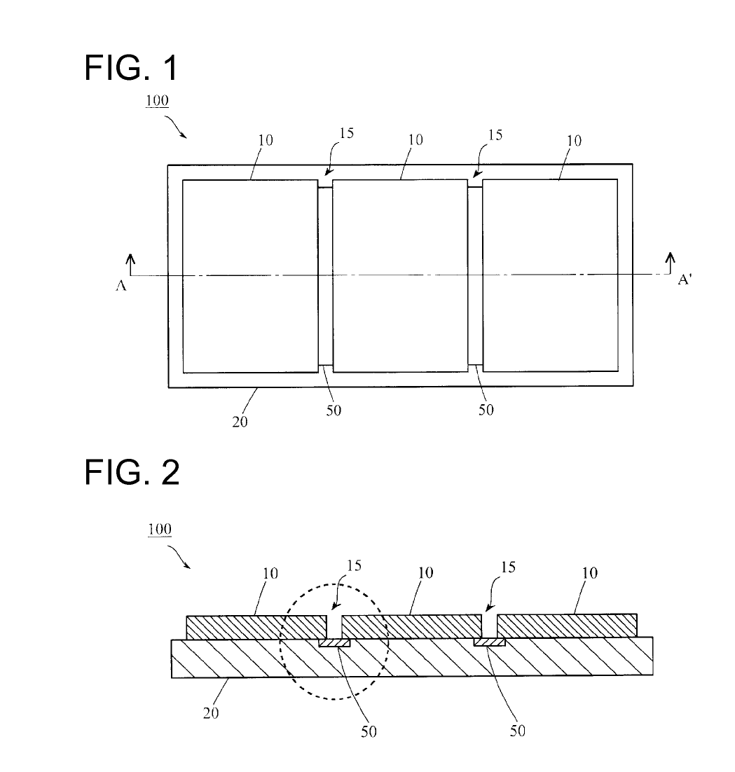

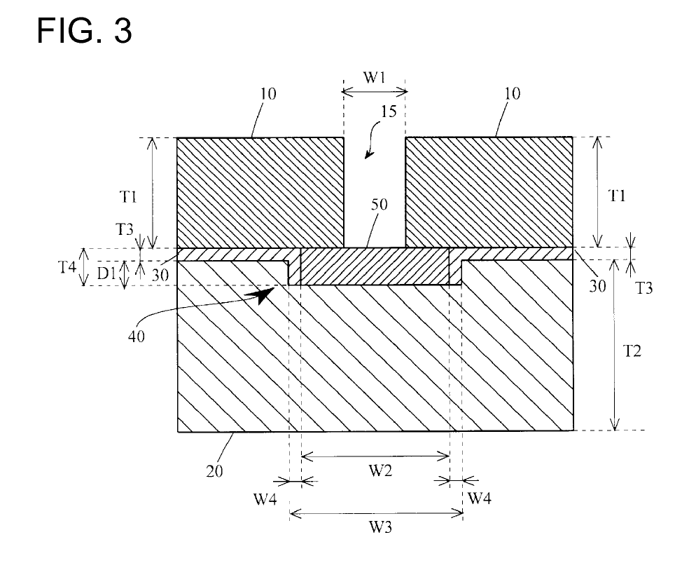

The configuration of a sputtering target according to Embodiment 1 of the present invention will be described with reference to FIGS. 1 to 3. FIG. 1 is a plan view of a configuration of a sputtering target 100 of the present embodiment. FIG. 2 is a cross-sectional view along the line A-A′ of the sputtering target 100 shown in FIG. 1. FIG. 3 is a magnified view of a portion (portion surrounded by the dotted line) of the cross-sectional view of FIG. 2.

The sputtering target 100 of the present embodiment is a segmented sputtering target constituted of a plurality of plate shaped target members 10 made of the same material as each other, a backing plate 20 as a plate shaped supporting member, a bonding agent 30, and plate-shaped protective members 50. The sputtering target 100 of the present embodiment differs from the conventional sputtering target 190 in being provided with the protective members 50. The protective members 50 are made of the same material as the respective target members 10 as will be described later. FIGS. 1 and 2 show an example in which three target members 10 are arranged in a row horizontally, but the present invention is not limited thereto.

The plurality of target members 10 and the backing plate 20 are bonded together through the bonding agent 30. In order to prevent cracking and the like in the target members 10, small gaps are provided in seams 15 between adjacent target members 10. As shown in FIG. 3, the seams 15 are formed so as to be perpendicular to the surface of the backing plate 20, but the configuration is not limited thereto.

Grooves 40 are formed in portions of the surface of the backing plate 20 corresponding in position to the respective seams 15. The respective grooves 40 are provided with the protective members 50. A width W2 of the protective members 50 is greater than a width W1 of the seams 15 but less than a width W3 of the grooves 40. A thickness T4 of the protective members 50 is greater than a depth D1 of the grooves 40. In other words, the surfaces of the protective members 50 protrude above the surface of the backing plate 20. The surfaces of the protective members 50 may alternatively be made to protrude above the surface of the backing plate 20 by providing the protective members with a thickness T4 of less than the depth D1 of the grooves 40 and inserting another member between the protective members 50 and the backing plate 20. Portions of the surface of each protective member 50 respectively towards the target members on both sides of the seam 15 above the protective member 50 (the respective left and right portions of the surface in FIG. 3) are respectively in contact with the target members 10 on both sides thereof.

With such a configuration, the protective members 50 and the target members 10 are in direct contact with each other, and thus, it is possible to prevent the bonding agent 30 from overflowing at the seams 15. Also, a space with a depth D1 and a width of W4 (W3−W2) is formed between each of the side faces of the protective member 50 and the backing plate 20, and thus, the effect of preventing the bonding agent 30 from overflowing at the seams 15 is further increased. The protective members 50 function as spacers, and thus, the thickness of the bonding agent 30 can be made even. In FIG. 3, the width W4 of the spaces formed between the respective side faces of the protective members 50 and the backing plate 20 is the same as the thickness T3 of the bonding agent 30, but the configuration is not limited thereto.

The respective target members 10 are made of IGZO, which is an oxide semiconductor having In, Ga, Zn, and O as main components. However, the material of the respective target members 10 is not limited thereto, and may be an oxide semiconductor including at least one of In, Ga, Zn, Cu, silicon (Si), tin (Sn), Al, calcium (Ca), germanium (Ge), and lead (Pb) (the so-called IGZO-type oxide semiconductor). The respective target members 10 may be a non-oxide semiconductor (Si, for example).

The material for the backing plate 20 has no special limitation and includes Cu and the like having excellent electrical and heat conductivity, for example. The material for the bonding agent 30 also has no special limitation, and includes In and the like, for example.

The material for the protective members 50 is IGZO as in the respective target members 10. Thus, IGZO is also sputtered at the seams 15.

### 1.2 Method of Manufacturing Sputtering Target

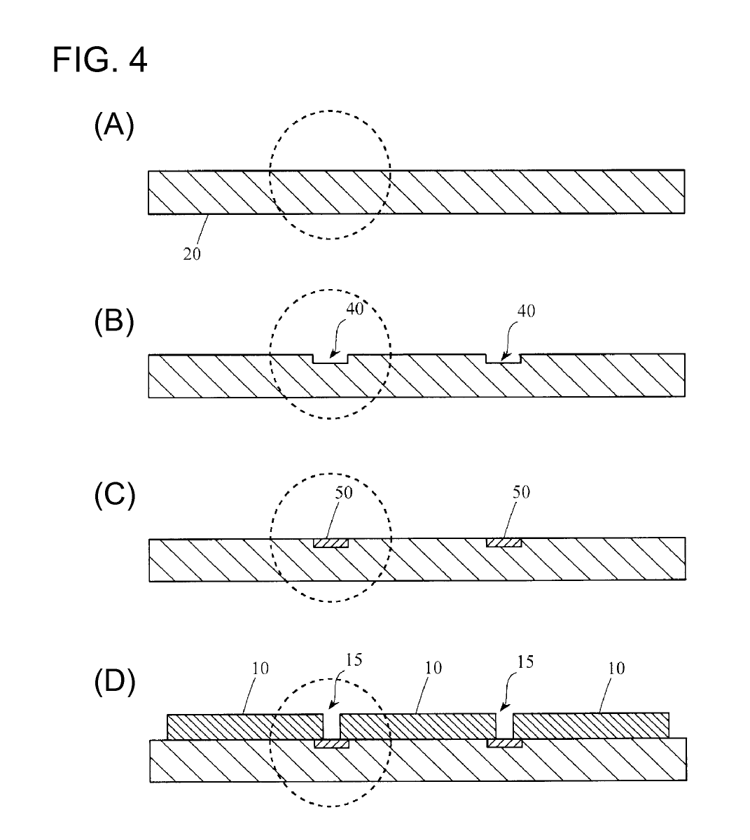

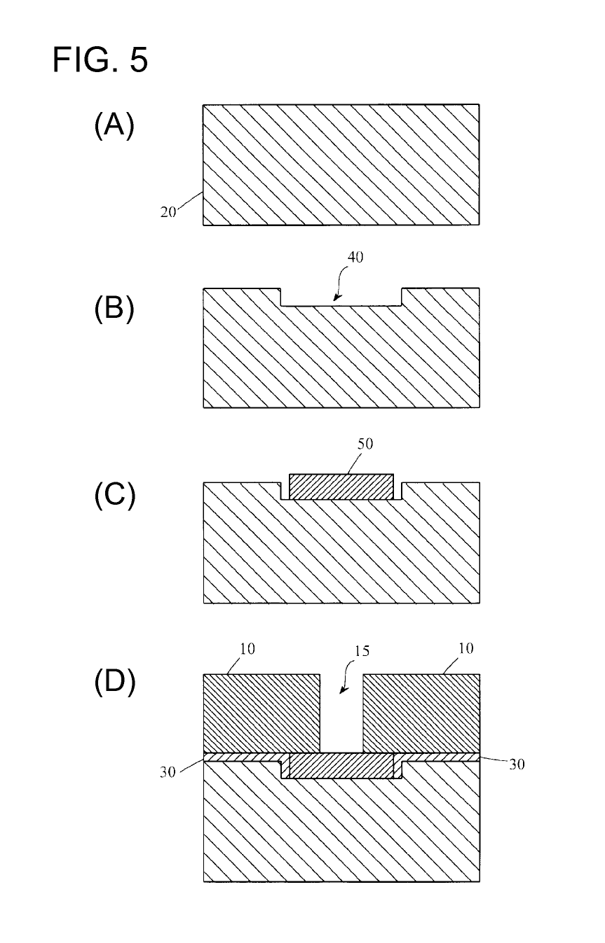

A method of manufacturing the sputtering target 100 of the present embodiment will be described with reference to FIGS. 4(A) to 4(D) and FIGS. 5(A) to 5(D). FIGS. 4(A) to 4(D) are cross-sectional views along the line A-A′ of the sputtering target 100 shown in FIG. 1 in order to describe the method of manufacturing the sputtering target 100 of the present embodiment. FIGS. 5(A) to 5(D) are respectively magnified views of portions of FIGS. 4(A) to 4(D).

First, grooves 40 (FIGS. 4(B) and 5(B)) are formed using a lathe or the like in the surface of the plate-shaped backing plate 20 (FIGS. 4(A) and 5(A)) made of Cu or the like. The grooves 40 may also be formed by grinding using a disc grinder or the like or melting or the like using lasers or the like, instead of lathing with a lathe or the like.

Next, plate-shaped protective members 50 made of IGZO are embedded into the formed grooves 40 (FIGS. 4(C) and 5(C)).

Next, while pressing the three target members 10 onto the backing plate 20 such that the seams 15 therebetween are on the corresponding protective members 50, a melted bonding agent 30 is filled between the three target members 10 and the backing plate 20. At this time, it is preferable that the target members 10 be attached to each other using a tape (an insulating tape, for example). If using an insulating tape, the insulating tape is peeled off thereafter.

Then, the bonding agent 30 is solidified by being cooled. As a result, the three target members 10 are bonded to the backing plate 20 through the bonding agent 30, and the protective members 50, the target members 10 respectively on both sides of the respective protective members 50, and the backing plate 20 are all attached to each other (FIGS. 4(D) and 5(D)). At this time, the seams 15 are formed at a width of W1. The width W1 can be accurately set by attaching together the target members 10 using the insulating tape as described above.

With the method above, the sputtering target 100 according to the present embodiment is manufactured.

### 1.3 Configuration of TFT and Method of Manufacturing TFT

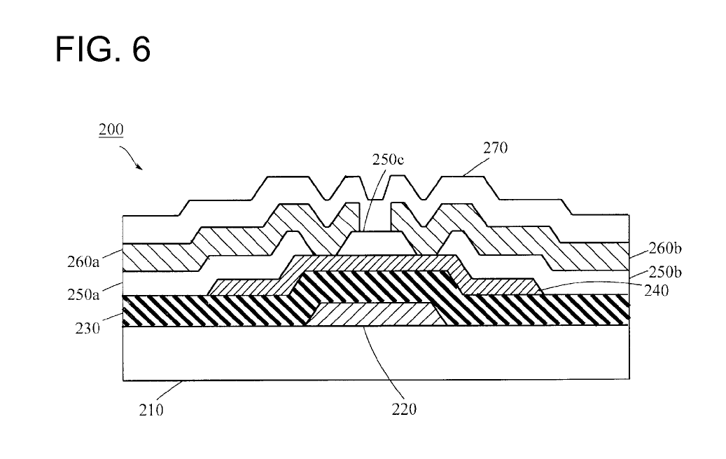

FIG. 6 is a cross-sectional view showing a configuration of a TFT 200 in which the channel layer thereof is formed using the sputtering target 100 of the present embodiment. The configuration of the TFT 200 of the present embodiment is similar to that of the TFT 290 in the basic study above, and thus, descriptions thereof will be omitted.

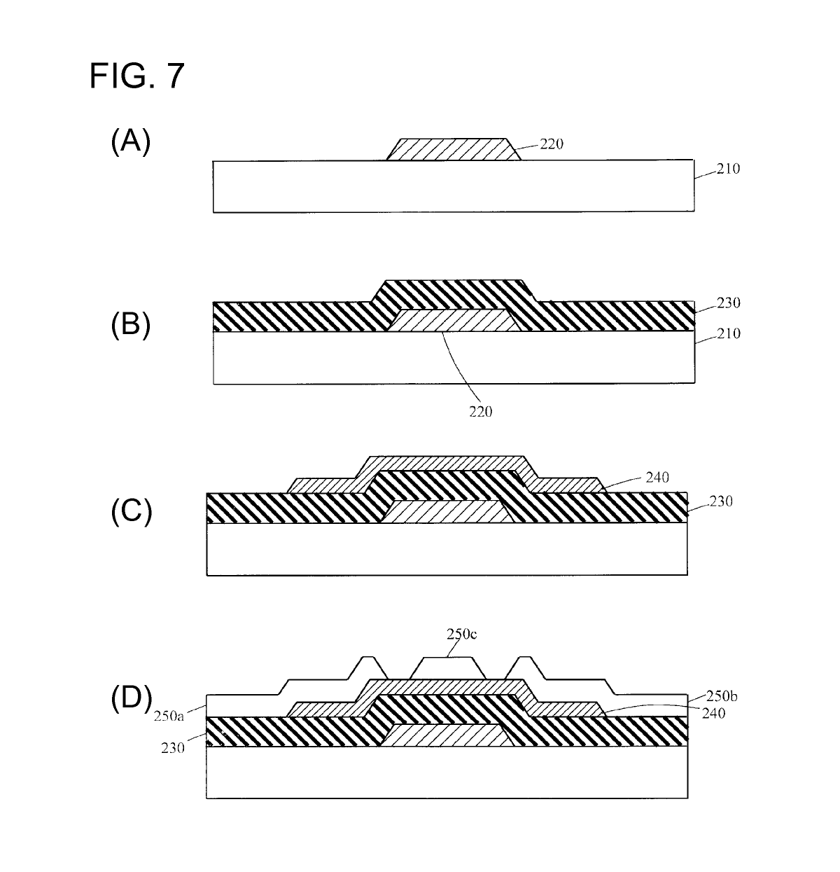

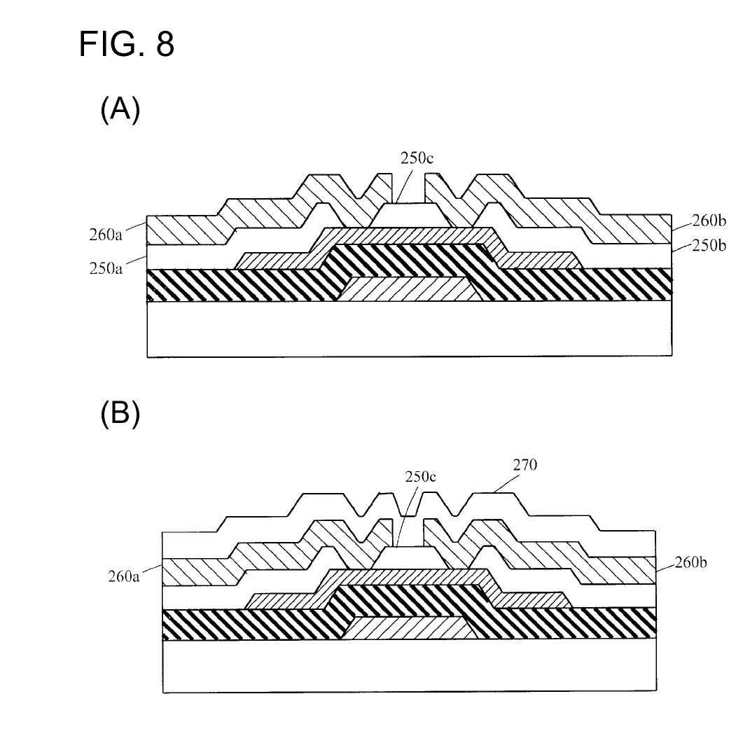

FIGS. 7(A) to 7(D) and FIGS. 8(A) and 8(B) are cross-sectional views for describing steps of manufacturing the TFT 200 of the present embodiment. In FIGS. 7(A) to 7(D) and FIGS. 8(A) and 8(B), depictions of the resist pattern are omitted for ease of description.

On the insulating substrate 210 made of glass or the like, a multilayer film including a Ti film 30 nm in thickness, an Al film 200 nm in thickness, and a Ti film 100 nm in thickness layered in this order is formed by sputtering. Next, a resist pattern is formed by photolithography in the upper center of the multilayer film. Then, by etching the multilayer film using this resist pattern as a mask, a gate electrode 220 is formed (FIG. 7(A)). Dry etching is used as the etching method, for example.

Next, after stripping the resist pattern, an SiN_{X} film 325 nm in thickness and an SiO₂ film 50 nm in thickness are layered in this order by plasma CVD on the insulating substrate 210 upon which the gate electrode 220 is formed. As a result, the gate insulating film 230 is formed (FIG. 7(B)).

An IGZO semiconductor film is formed on the gate insulating film 230. The IGZO semiconductor film may be formed by DC magnetron sputtering or RF magnetron sputtering. With DC magnetron sputtering, for example, as shown in FIG. 24 above, a magnet 300 is disposed on the rear surface of the sputtering target 100 (surface on the side of the backing plate 20) of the present embodiment, and a DC voltage is applied between the sputtering target 100 and the substrate 211. The substrate 211 is the insulating substrate 210 up to when the gate electrode 220 and the gate insulating film 230 have been layered on the surface thereof. Ar gas or the like is used as the sputtering gas.

As a DC voltage is applied, Ar ions are accelerated, and collide with the surface of the target members 10 of the sputtering target 190. As a result, atoms are flicked off (sputtered) from the surface of the target members 10, and reach the substrate 211. In this manner, the sputtered material from the target members 10 is deposited onto the substrate 211, thus forming the IGZO semiconductor film.

Then, a resist pattern is formed by photolithography on the upper center of the IGZO semiconductor film. Then, by etching the IGZO semiconductor film with this resist pattern as a mask, the channel layer 240 is formed (FIG. 7(C)). Wet etching is used as the etching method, for example.

Next, after the resist pattern is stripped, an etching stopper layer made of an SiO₂ film 150 nm in thickness is formed by plasma CVD on the insulating substrate 210 on which the channel layer 240 is formed. Next, a resist pattern is formed by photolithography on the upper left, upper right, and upper center of the etching stopper layer in FIG. 7(D). By etching the etching stopper layer 250 as a resist pattern, etching stopper layers 250a, 250b, and 250c are respectively formed in the upper left, upper right, and upper center of the channel layer 240 (FIG. 7(D)). At this time, contact holes are formed between the etching stopper layers 250a and 250c, and between the etching stopper layers 250b and 250c. Dry etching is used as the etching method, for example.

Next, after stripping the resist pattern, a multilayer film having a Ti film 30 nm in thickness and an Al film 200 nm in thickness layered in this order is formed by sputtering so as to cover the entire insulating substrate 210. Instead of such a multilayer film, a single layer metal film such as Ti, Al, Cu, Mo, W, or Cr, or an alloy film including TiN or MoN, or a multilayer film including these may be formed. Next, by photolithography, resist patterns are formed on the multilayer film at positions corresponding to the etching stopper layer 250a, the channel layer 240 where the surface thereof is exposed between the etching stopper layers 250a and 250c, and on the left edge of the etching stopper layer 250c, and at positions corresponding to the etching stopper layer 250b, the channel layer 240 where the surface thereof is exposed between the etching stopper layers 250b and 250c, and the right edge of the etching stopper layer 250c. Then, the multilayer film is etched with the resist pattern as a mask. As a result, a source electrode 260a is formed so as to cover the etching stopper layer 250a, the channel layer 240 having a surface thereof exposed between the etching stopper layers 250a and 250c, and the left edge of the etching stopper layer 250c, and a drain electrode 260b is formed so as to cover the etching stopper layer 250b, the channel layer 240 having a surface thereof exposed between the etching stopper layers 250b and 250c, and the right edge of the etching stopper layer 250c (FIG. 8(A)). At this time, the surface of the channel layer 240 is covered by the etching stopper layer 250c, and thus, the surface of the channel layer 240 is not etched. Wet etching is used as the etching method, for example.

Next, after the resist pattern is stripped, a protective film 270 made of SiO₂ 200 nm in thickness is formed by plasma CVD so as to cover the entire insulating substrate 210 (FIG. 8(B)).

The TFT 200 of the present embodiment can be manufactured by the steps above.

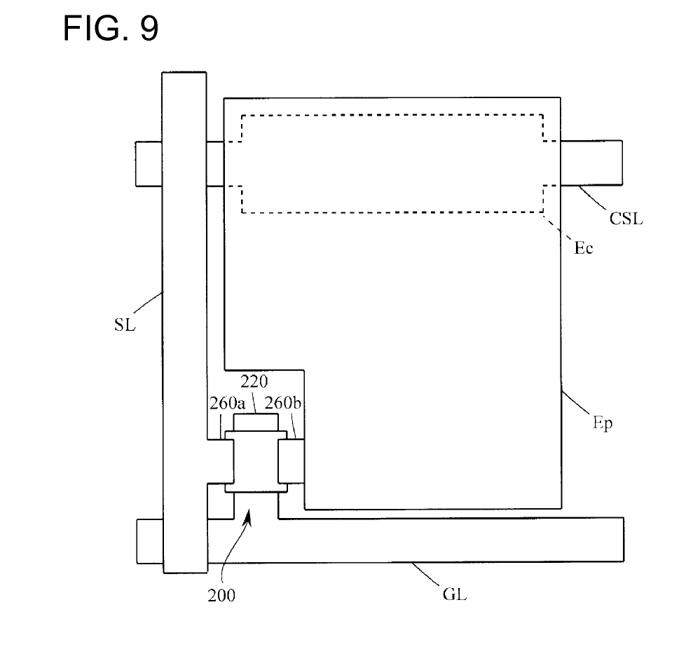

FIG. 9 shows a portion of an active matrix substrate of a liquid crystal display device in which the TFT 200 having the channel layer 240 formed using the sputtering target 100 of the present embodiment is provided as a pixel TFT. The active matrix substrate is constituted of a plurality of source lines SL and a plurality of gate lines GL arranged in a grid pattern so as to intersect with each other on the insulating substrate 210, TFTs 200 provided for the respective intersection points of the plurality of source lines SL and the plurality of gate lines GL, pixel electrodes Ec, auxiliary capacitance electrodes Ec, and auxiliary capacitance lines CSL disposed along the respective gate lines GL. The auxiliary capacitance lines CSL are connected to the auxiliary capacitance electrodes Ec. Liquid crystal fills the space between the pixel electrodes Ep and the opposing common electrode (not shown in drawings). Liquid crystal capacitance is generated between the pixel electrodes Ep and the common electrode, and auxiliary capacitance is generated between the pixel electrodes Ep and the auxiliary capacitance lines CSL.

The TFTs 200 are provided for the respective intersection points between the source lines SL and the gate lines GL, which intersect with each other. The source electrode 260a of the TFT 200 is connected to the source line SL, the gate electrode 220 is connected to the gate line GL, and the drain electrode 260b is connected to the pixel electrode Ep. If an etching stopper layer is present as in the present embodiment, the drain electrode 260b is connected to the pixel electrode Ep through a contact hole (not shown in drawings).

A plurality of source signals are applied to the respective plurality of source lines SL and a plurality of gate signals are applied to the respective plurality of gate lines GL, and as a result, a voltage corresponding to the pixel value of the pixel to be displayed is applied to the pixel electrode through the TFT 200 with the potential applied to the common electrode as a reference, and is stored at a pixel capacitance composed of a liquid crystal capacitance and an auxiliary capacitance. As a result, a voltage corresponding to the difference in potential between the pixel electrodes and the common electrode is applied to the liquid crystal layer. Images are displayed by controlling the light transmittance of the liquid crystal layer by the applied voltage.

### 1.4 Study

The inventors of the present invention conducted an experiment to measure characteristics of the TFTs 200 in which the channel layers 240 thereof are formed using the sputtering target 100 of the present embodiment. In the sputtering target 100 used in this experiment, a thickness T1 of the respective target members 10 was 6.0 mm, a thickness T2 of the backing plate 20 was 10.0 mm, a thickness T3 of the bonding agent 30 was 0.3 mm, a thickness T4 of the protective members 50 was 2.0 mm, a depth D1 of the grooves 40 was 1.7 mm, a width W1 of the seams 15 was 0.3 mm, a width W2 of the protective members 50 was 9.4 mm, a width W3 of the grooves 40 was 10.0 mm, and a width W4 of the spaces between the respective side faces of the protective members 50 and the backing plate 20 was 0.3 mm. The length of the channel of the TFT 200 was 8 μm, and the width of the channel was 20 μm.

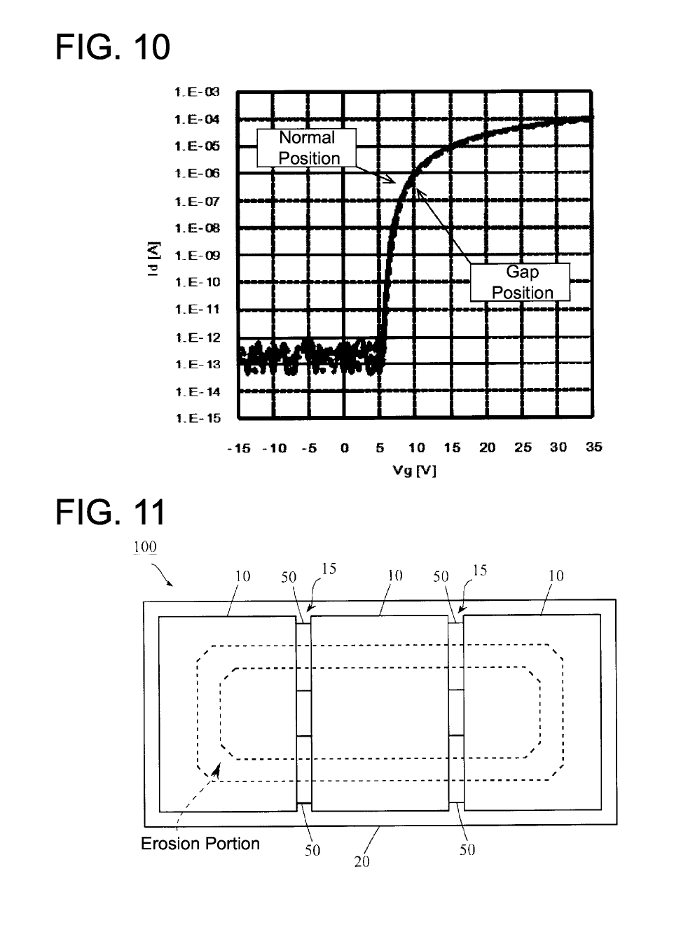

FIG. 10 shows the Id-Vg characteristics of the TFTs 200 in which the channel layers 240 thereof were formed using the sputtering target 100 of the present embodiment. Here, Id represents the drain current, and Vg represents the gate voltage. The solid line represents the characteristics of the TFTs 200 formed in the normal positions and the dotted line represents the characteristics of the TFTs 200 formed in the seam positions.

With the TFTs 290 having the channel layers 240 thereof formed using the conventional sputtering target 190, as stated above, the TFTs 290 formed in the seam positions had worse Id-Vg characteristics compared to the TFTs 290 formed in the normal positions. On the other hand, with the TFTs 200 having the channel layers 240 thereof formed using the sputtering target 100 of the present embodiment, the Id-Vg characteristics of the TFTs 200 formed in the normal positions is virtually identical to the Id-Vg characteristics of the TFTs 200 formed in the normal positions.

In the sputtering target 100 of the present embodiment, portions of the backing plate 20 corresponding to the seams 15 are covered by the protective members 50 made of the same material as the target members 10, and thus, material from the backing plate 20 is not sputtered. Also, as stated above, the bonding agent 30 is prevented from overflowing at the seams 15, and thus, the bonding agent 30 is also not sputtered. Therefore, material from the bonding agent 30 and the backing plate 20 is not mixed into the channel layer 240 (semiconductor film) as impurities. As a result, in the TFTs 200 with the channel layers 240 thereof formed using the sputtering target 100 of the present embodiment, the characteristics of the TFTs 200 formed in the seam positions is virtually identical to the characteristics of the TFTs 200 formed in the normal positions.

### 1.5 Effects

According to the present embodiment, the protective members 50 made of the same material as the target members 10 are provided on the surface of the backing plate 20 in portions corresponding in position to the seams 15 between the respective adjacent target members 10. The protective members 50 and the target members 10 are in direct contact, and spaces are formed between the respective side faces of the protective members 50 and the backing plate 20, and thus, overflow of the bonding agent 30 at the seams 15 is sufficiently mitigated. Thus, material from the backing plate 20 and the bonding agent 30 is not sputtered at the seams 15. As a result, it is possible to prevent material from the backing plate 20 and the bonding agent 30 from being mixed into the semiconductor film as impurities, and thus, a semiconductor film with excellent characteristics can be obtained.

### 1.6 Modification Example 1

FIG. 11 is a plan view of a configuration of a sputtering target 100 of Modification Example 1 of the present embodiment. In a sputtering target 100 of the present modification example, protective members 50 are provided in positions corresponding to an erosion portion (portion in FIG. 11 surrounded by the dotted lines) in positions on the surface of the backing plate 20 corresponding to the seams 15, and thus, protective members 50 are not formed in other positions. The “erosion portion” refers to a region on the target members 10 where erosion progresses quickly.

The protective members 50 are provided only in portions of the surface of the backing plate 20 corresponding to the seams 15, and thus, the bonding agent 30 can fill portions where the protective members 50 are not formed. As a result, the bonding strength between the target members 10 and the backing plate 20 can be improved.

In a fixed magnet-type magnetron sputtering device with a fixed magnet 300, erosion progresses only in specific regions. Thus, the present modification example is suitable for use with a fixed magnet-type magnetron sputtering device.

### 1.7 Modification Example 2

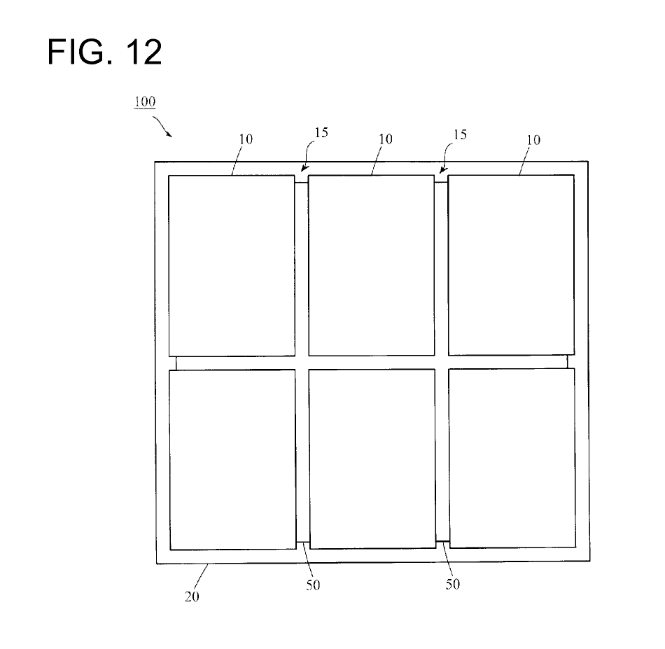

FIG. 12 is a plan view of a configuration of a sputtering target 100 of Modification Example 2 of the present embodiment. In the sputtering target 100 of the present modification example, the target members 10 are arranged along the horizontal and vertical directions. In the present modification example, seams 15 are present not only between target members 10 adjacent to each other in the horizontal direction, but also between target members 10 adjacent to each other in the vertical direction. Thus, the protective members 50 extend vertically and horizontally. The present modification example is suitable for use with a large display panel.

### 1.8 Modification Example 3

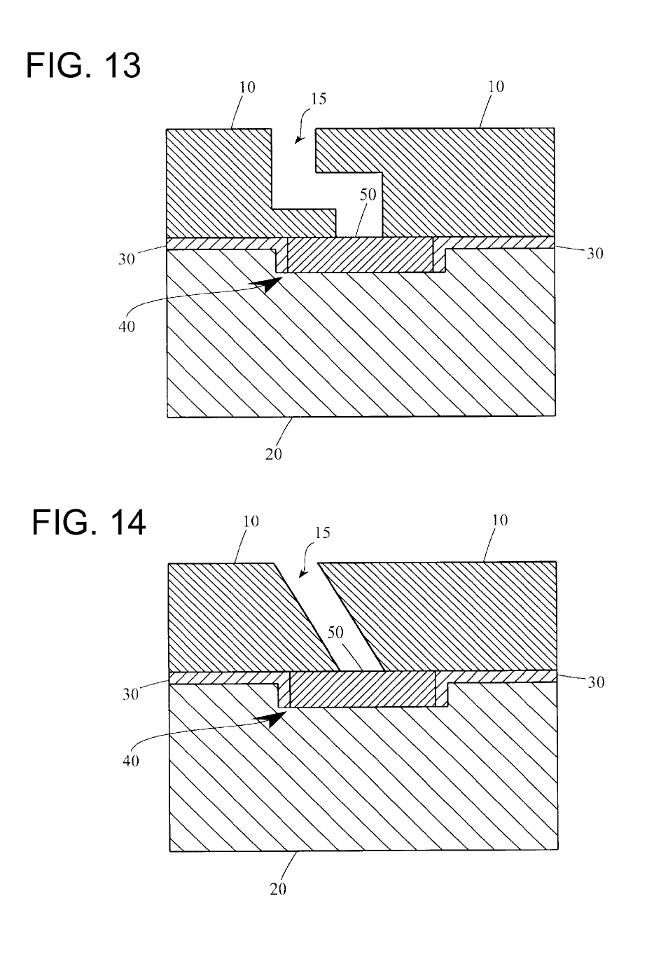

FIG. 13 is a cross-sectional view of a portion of a sputtering target 100 according to Modification Example 3 of the present embodiment. In the present modification example, the seams 15 are formed in a step shape. In the present embodiment, even if the seams 15 cannot maintain their step shape during sputtering, the protective members 50 are provided, and thus, it is possible to prevent the backing plate 20 and the bonding agent 30 from being sputtered. Besides the present modification example, similar effects can be attained even if the seams 15 have an inclined shape as in FIG. 14, for example.

### 2. Embodiment 2

### 2.1 Configuration of Sputtering Target

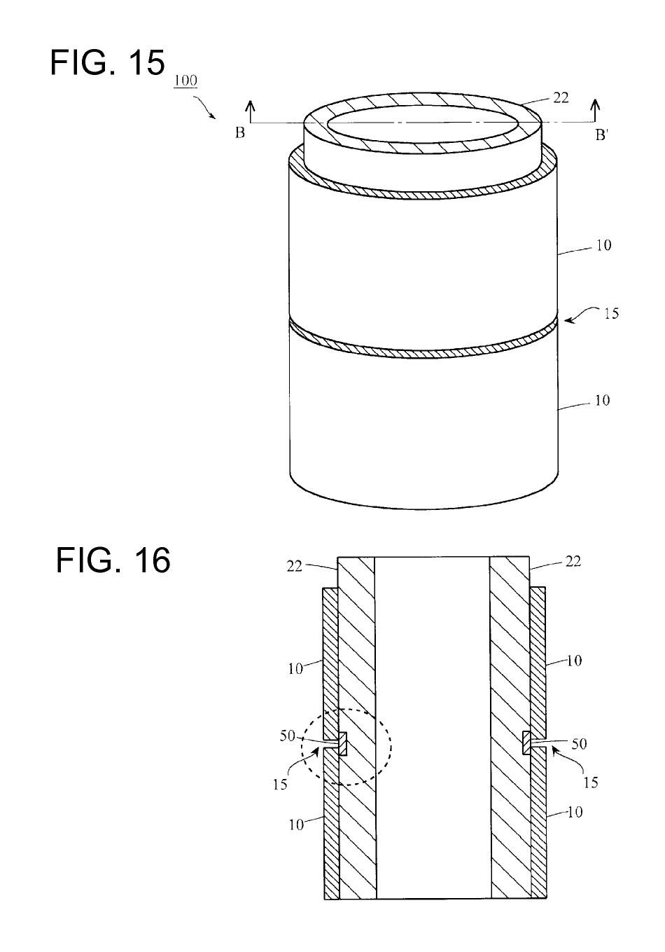

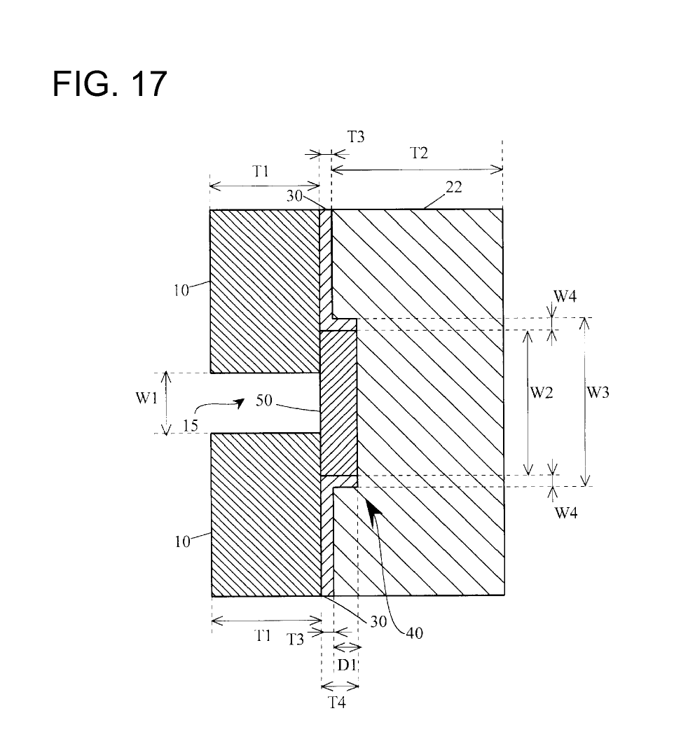

The configuration of a sputtering target according to Embodiment 2 of the present invention will be described with reference to FIGS. 15 to 17. Of components in the present embodiment, components that are the same as those of the sputtering target 100 of Embodiment 1 are assigned the same reference characters and descriptions thereof will be omitted. FIG. 15 is a perspective view of a configuration of the sputtering target 100 of the present embodiment. FIG. 16 is a cross-sectional view along the line B-B′ of the sputtering target 100 shown in FIG. 15. FIG. 17 is a magnified view of a portion (portion surrounded by the dotted line) of the cross-sectional view of FIG. 16.

In the sputtering target 100 of the present embodiment, instead of a plurality of plate shaped target members 10, a plate-shaped backing plate 20, and plate-shaped protective members 50, a plurality of hollow cylinder target members 10 made of the same material (IGZO), a backing tube 22 as a hollow cylinder support member, and a ring shaped protective member 50 are provided. In other words, the sputtering target 100 of the present embodiment is a segmented sputtering target constituted of a plurality of hollow cylinder target members 10, a backing tube 22, a bonding agent 30, and a ring shaped protective member 50. The outer diameter and inner diameter of the protective member 50 are less than the respective outer diameter and inner diameter of the target members 10. Also, the outer diameter of the protective member 50 is slightly greater than the outer diameter of the backing plate 20, and the inner diameter of the protective member 50 is also greater than the inner diameter of the backing plate 20. FIGS. 15 and 16 show an example in which two target members 10 are arranged in a row, but the present invention is not limited thereto. For example, three or more target members 10 may be arranged in a row.

As shown in FIG. 17, the seam 15 is formed so as to be perpendicular to the surface of the backing tube 22, but the configuration is not limited thereto. For example, as in Modification Example 2 of Embodiment 1, the seam 15 may have a step shape or an inclined shape.

A groove 40 is formed in a portion of the surface of the backing tube 22 corresponding to the seam 15. The groove 40 is provided with the protective member 50. A width W2 of the protective member 50 is greater than a width W1 of the seam 15 but less than a width W3 of the groove 40. A thickness T4 of the protective member 50 is greater than a depth D1 of the groove 40. In other words, the surface of the protective member 50 protrudes above the surface of the backing tube 22. The surface of the protective member 50 may alternatively be made to protrude above the surface of the backing tube 22 by providing the protective member with a thickness T4 less than the depth D1 of the groove 40 and inserting another member between the protective member 50 and the backing tube 22. Portions of the surface of the protective member 50 respectively towards the target members on both sides of the seam 15 above the protective member 50 (the respective upper and lower portions of the surface in FIG. 17) are respectively in contact with the target members 10 on both sides thereof.

With such a configuration, the protective member 50 and the target members 10 are in direct contact with each other, and thus, it is possible to prevent the bonding agent 30 from overflowing at the seam 15 even when using hollow cylinder target members 10. Also, spaces with a depth D1 and a width of W4 (W3−W2) are formed between the respective side faces of the protective member 50 and the backing tube 22, and thus, the effect of preventing the bonding agent 30 from overflowing at the seam 15 is further increased. The protective member 50 functions as a spacer, and thus, the thickness of the bonding agent 30 can be made even. In FIG. 17, the width W4 of the spaces formed between the respective side faces of the protective member 50 and the backing tube 22 is the same as the thickness T3 of the bonding agent 30, but the configuration is not limited thereto. The bonding agent 30 may be present between the protective member 50 and the bottom surface of the groove 40.

### 2.2 Method of Manufacturing Sputtering Target

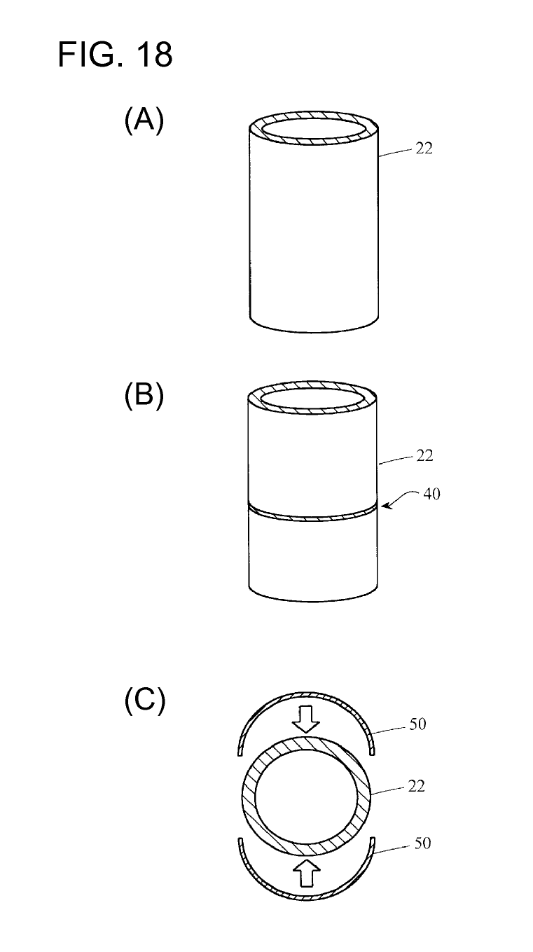

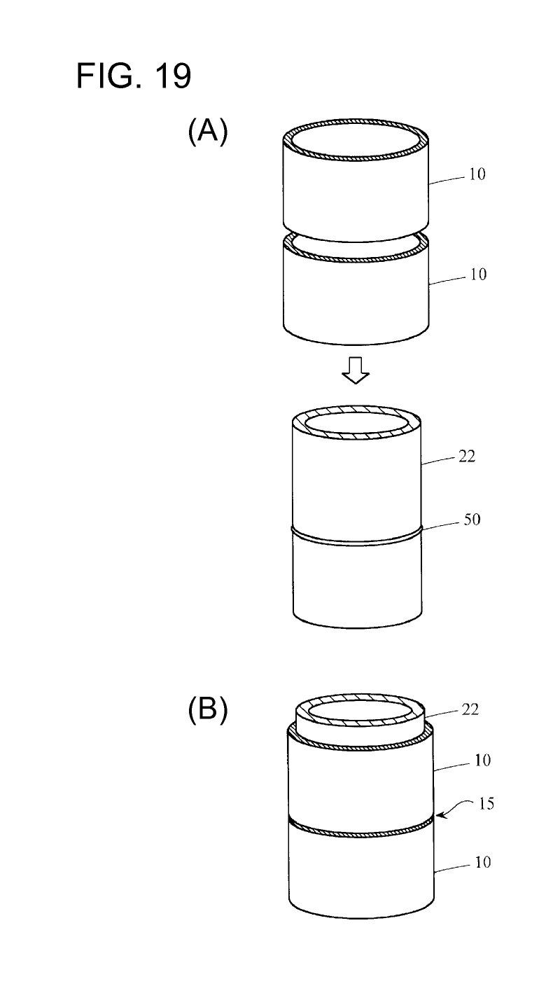

A method of manufacturing the sputtering target 100 of the present embodiment will be described with reference to FIGS. 18(A) to 18(C) and FIGS. 19(A) and 19(B).

First, the groove 40 is formed (FIG. 18(B)) using a lathe or the like on the surface of the backing tube 22 (FIG. 18(A)) made of Cu or the like. The groove 40 may also be formed by grinding using a disc grinder or the like or melting or the like using lasers or the like, instead of lathing with a lathe or the like.

Next, two arc shaped protective members 50 made of IGZO are embedded into the formed groove 40 (FIG. 18(C)). One ring shaped protective member 50 is formed of the two arc shaped protective members 50.

Next, two target members 10 are fitted onto the backing tube 22 such that the seam 15 therebetween is positioned over the corresponding protective member 50 (FIG. 19(A)). At this time, it is preferable that the two target members 10 be attached to each other using a tape (an insulating tape, for example). Next, a melted bonding agent 30 is injected between the two target members 10 and the backing tube 22. If using an insulating tape, the insulating tape is peeled off thereafter.

Then, the bonding agent 30 is solidified by being cooled. As a result, the two target members 10 are bonded to the backing tube 22 through the bonding agent 30, and the protective member 50, the target members 10 on both sides of the protective member 50, and the backing tube 22 are bonded together. At this time, the seam 15 is formed at a width of W1. The width W1 can be accurately set by attaching together the target members 10 using the insulating tape as described above.

With the method above, the sputtering target 100 according to the present embodiment is manufactured.

### 2.3 Effects

According to the present embodiment, effects similar to those of Embodiment 1 can be attained when using hollow cylinder target members 10.

In the present embodiment also, as in Modification Example 1 of Embodiment 1, a configuration in which the protective member 50 is provided only in a portion corresponding to the erosion portion can be used.

### 3. Other Configurations

The sputtering target 100 of the present invention can be used to form not only a semiconductor film, but also a conductive film or the like.

In Embodiment 1, an example was shown of a bottom gate TFT with an etching stopper structure, but the present invention is not limited thereto. For example, the present invention may be applied to TFTs having a channel etching structure, a top gate structure, and the like.

In Embodiment 2, a hollow cylinder supporting member (backing tube 22) was used, but a non-hollow cylinder supporting member may be used instead.

Embodiments and modification examples of the present invention were described, but the present invention is not limited thereto. Various modifications can be made without departing from the spirit of the present invention.

According to the present invention above, it is possible to provide a sputtering target with which it is possible to obtain a film with excellent characteristics. Also, according to the present invention, it is possible to provide a method of manufacturing a sputtering target with which it is possible to obtain a film with excellent characteristics. Furthermore, according to the present invention, it is possible to provide a manufacturing method for a thin film transistor using a sputtering target with which it is possible to obtain a semiconductor film with excellent characteristics.

### INDUSTRIAL APPLICABILITY

The present invention can be applied to a sputtering target used to form a semiconductor film or the like.

### DESCRIPTION OF REFERENCE CHARACTERS

10 target member
15 seam
20 backing plate (supporting member)
22 backing tube (supporting member)
30 bonding agent
40 groove
50 protective member
100, 190 sputtering target
200, 290 TFT (thin film transistor)
240 channel layer

1. A sputtering target, comprising:
a plurality of target members made of the same material as each other;
a supporting member that supports the plurality of target members;
a bonding agent that bonds the plurality of target members to the supporting member; and
a protective member made of the same material as the respective target members,
wherein a portion of a surface of the supporting member corresponding in position to a gap between adjacent target members has a groove therein,
wherein a width of the groove is greater than a width of the gap,
wherein a width of the protective member is greater than the width of the gap and less than the width of the groove,
wherein the protective member is provided in the groove,
wherein a surface of the protective member protrudes above the surface of the supporting member, and
wherein portions of the surface of the protective member are in contact with portions of the respective adjacent target members.

2. The sputtering target according to claim 1, wherein the respective target members and the protective member are made of a semiconductor.

3. The sputtering target according to claim 2, wherein the semiconductor is an oxide semiconductor.

4. The sputtering target according to claim 3, wherein the oxide semiconductor includes indium, gallium, zinc, and oxygen as main components.

5. The sputtering target according to claim 3, wherein the oxide semiconductor includes at least one of indium, gallium, zinc, copper, silicon, tin, aluminum, calcium, germanium, and lead.

6. The sputtering target according to claim 2, wherein a thickness of the protective member is greater than a depth of the groove.

7. The sputtering target according to claim 2,
wherein the supporting member has a plate shape, and
wherein the respective target members have plate shapes.

8. The sputtering target according to claim 2,
wherein the supporting member has a hollow cylindrical shape or a non-hollow cylindrical shape, and
wherein the respective target members have hollow cylindrical shapes.

9. The sputtering target according to claim 2, wherein the protective member is provided in a position corresponding to a portion where erosion of the plurality of target members progresses quickly.

10. A method of manufacturing a thin film transistor, comprising forming a channel layer by sputtering the sputtering target according to claim 2.

11. A method of manufacturing a sputtering target that includes a plurality of target members made of the same material as each other, a supporting member that supports the plurality of target members, and a bonding agent that bonds together the plurality of target members and the supporting member, the method comprising:
forming a groove in a portion of a surface of the supporting member corresponding in position to a gap between adjacent target members; and
embedding a protective member made of the same material as the respective target members into the groove,
wherein a width of the groove is greater than a width of the gap,
wherein a width of the protective member is greater than the width of the gap and less than the width of the groove,
wherein a surface of the protective member protrudes above the surface of the supporting member, and
wherein portions of the surface of the protective member are in contact with portions of the respective adjacent target members.
